(19) United States
(12) Patent Application Publication
(10) Pub. No.: US 2026/0206506 A1
(43) Pub. Date: Jul. 16, 2026

(54) SYSTEM AND METHOD TO ENABLE EFFICIENT CHANNEL IMPLANT WITH XRD

(71) Applicant: Axcelis Technologies, Inc., Beverly, MA (US)

(72) Inventors: FHM Faridur Rahman, Boxford, MA (US); Fulvio Mazzamuto, Parma (IT); Neil J. Bassom, Hamilton, MA (US)

(21) Appl. No.: 19/443,190

(22) Filed: Jan. 8, 2026

Related U.S. Application Data
(60) Provisional application No. 63/743,765, filed on Jan. 10, 2025.

(51) Int. Cl. H10P 30/20; H10P 72/00; H10P 72/50

(52) U.S. Cl. CPC H10P 30/222; H10P 72/0606; H10P 72/53

(57) ABSTRACT

A workpiece having a crystalline lattice and an alignment feature is positioned on a first workpiece support. A first position of the workpiece is detected and emission x-rays from one or more x-ray sources are directed toward the workpiece on the first workpiece support and diffracted from the workpiece to define diffraction x-rays that are detected. One or more angles associated with the crystalline lattice are determined based on the diffraction x-rays and the first position of the alignment feature with respect to the x-ray sources to define a workpiece profile with respect to the alignment feature. The workpiece is transferred to a second workpiece support to detect a second position of the alignment feature. A position of the second workpiece support in a process chamber is controlled with respect an ion beam based on the workpiece profile and the second position of the alignment feature.

### REFERENCE TO RELATED APPLICATIONS

This application claims the benefit of U.S. Provisional Application Serial No. 63/743,765 filed January 10, 2025, entitled, “SYSTEM AND METHOD TO ENABLE EFFICIENT CHANNEL IMPLANT WITH XRD”, the contents of all of which is herein incorporated by reference in its entirety.

### FIELD OF THE INVENTION

The present invention relates generally to ion implantation systems, and more specifically to a system and method for providing efficient channeled ion implantation using x-ray diffraction.

### BACKGROUND

In semiconductor processing, many operations may be performed on a single workpiece or semiconductor wafer. In many processing operations, a particular orientation of the workpiece and/or knowledge of the position of the workpiece with respect to a workpiece holder is used to properly process or handle the workpiece. For example, operations such as an exchange of workpieces between transport carriers and a processing system may utilize specific orientation(s) or knowledge of the spatial position of the workpiece for proper workpiece handling and processing.

### SUMMARY

The present disclosure provides a system, apparatus, and method for determining an alignment of a workpiece with respect to a workpiece support via x-ray diffraction. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

According to one example aspect of the present disclosure, a method is provided for implanting ions into a crystalline lattice of a workpiece, whereby a workpiece is positioned on a first workpiece support, and wherein the workpiece comprises an alignment feature. A first position of the workpiece with respect to the first workpiece support is detected, and one or more emission x-rays are directed toward the workpiece from one or more x-ray sources when the workpiece is positioned on the first workpiece support. The one or more emission x-rays are diffracted from the workpiece to define one or more diffraction x-rays, respectively, and the one or more diffraction x-rays are further detected. In one example, one or more angles associated with the crystalline lattice of the workpiece are determined based on the one or more diffraction x-rays and the first position of the alignment feature of workpiece with respect to the one or more x-ray sources, thereby defining a workpiece profile with respect to the alignment feature of the workpiece.

The workpiece, for example, can be transferred to second workpiece support, and a second position of the workpiece with respect to the second workpiece support can be detected. A position of the second workpiece support with respect an ion beam, for example, can be controlled based on the workpiece profile and the second position of the alignment feature of the workpiece, whereby ions from the ion beam can be implanted into the workpiece in a predetermined manner.

In one example, detecting the first position of the workpiece with respect to the first workpiece support comprises detecting a position indicia defined on the workpiece, such as a notch or a flat associated with the workpiece, wherein the detection of the position indicia can be performed in an atmospheric environment. The second workpiece support, for example, can comprise an electrostatic chuck positioned within a process chamber.

The one or more x-ray sources, for example, can be fixed in position with respect to the first workpiece support. In one example, determining the one or more angles associated with the crystalline lattice of the workpiece comprises rotating the workpiece with respect to one or more one or more x-ray sources. In another example, the one or more x-ray sources comprise a plurality of x-ray sources, wherein determining the one or more angles associated with the crystalline lattice of the workpiece comprises fixing a rotational position of the workpiece concurrent with detecting the one or more diffraction x-rays.

In accordance with another exemplary aspect of the disclosure, an ion implantation system is provided, wherein the ion implantation system comprises an ion source configured to form an ion beam, a beam line assembly configured to direct the ion beam, and a process chamber configured to receive the ion beam. A process chuck is positioned within the process chamber, wherein the process chuck is configured to selectively support a workpiece with respect to the ion beam.

In accordance with one example, an x-ray diffraction measurement apparatus is located external to the process chamber, wherein the x-ray diffraction measurement apparatus comprises a measurement station comprising a measurement chuck configured to selectively support the workpiece. An x-ray source is configured to direct one or more emission x-rays toward the workpiece when the workpiece is supported on the measurement chuck, wherein the one or more emission x-rays are diffracted from the workpiece to define one or more diffraction x-rays, respectively. Further, an x-ray detector is configured to detect the one or more diffraction x-rays, and a controller is configured to control a position of the process chuck based, at least in part, on the one or more diffraction x-rays.

The x-ray diffraction measurement apparatus, for example, further comprises a manipulation apparatus operably coupled to the measurement chuck and configured to selectively position the workpiece with respect to the one or more emission x-rays. The x-ray source, for example, is fixed in position with respect to the measurement station. In one example, a manipulation apparatus can be further configured to selectively rotate the measurement chuck with respect to the x-ray source. In another example, a plurality of x-ray sources are configured to direct a respective plurality of x-rays toward the workpiece at a respective plurality of angles with respect to the workpiece, wherein the plurality of x-ray sources are fixed in position with respect to the measurement station.

In yet another example, a load port is further associated with a load chamber, wherein the load chamber is external to the process chamber and is operably coupled to the process chamber, and wherein the x-ray diffraction measurement apparatus is associated with the load port. the x-ray diffraction measurement apparatus is positioned at a remote location. A detection apparatus can be further configured to detect one or more features of the workpiece.

In accordance with yet another exemplary aspect of the disclosure, a method for processing a wafer comprises identifying the wafer and loading the wafer into an XRD module. X-ray diffraction (XRD) measurements can be associated with the wafer, the wafer can be positioned on a chuck in a process chamber, thereby defining a wafer position. In one example, a determination can be made whether a fingerprint of the wafer is matched with a predetermined wafer profile based, at least in part, on the XRD measurements, whereby a match error is defined if the fingerprint of the wafer is inconsistent with the predetermined wafer profile.

In one example, a determination can be made if the match error can be corrected by a corrective action, and the corrective action can be performed if the match error can be corrected. In another example, a non-compliant alarm action can be set if the match error cannot be corrected.

Further, a determination can be made whether a tilt angle of the wafer is consistent with an angle of the chuck based, at least in part, on the XRD measurements, wherein the match error is redefined if the tilt angle of the wafer is inconsistent with the angle of the chuck. A wafer angle adjustment can be made based, at least in part, on the XRD measurements, thereby providing a desired crystal cut, and an ion implantation can be performed on the wafer after the wafer angle adjustment is performed.

In one example, the match error comprises a positioning error associated with the wafer position, and wherein the corrective action comprises a correction to the wafer position. In a further example, a determination can be made whether the tilt angle of the wafer is stable concurrent with the ion implantation being performed on the wafer. The ion implantation can be further halted if the tilt angle is not stable concurrent with the ion implantation.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic view of an ion implantation system in accordance with various examples of the present disclosure.

FIG. 2 is a top elevation view of a workpiece alignment apparatus in accordance with various examples of the present disclosure.

FIG. 3A is a top elevation view of a first example of an ion implantation system in accordance with various examples of the present disclosure.

FIG. 3B is a top elevation view of a second example of an ion implantation system in accordance with various examples of the present disclosure.

FIG. 3C is a top elevation view of a third example of an ion implantation system in accordance with various examples of the present disclosure.

FIG. 4A is perspective view of a first XRD setup having a single XRD source and a single fixed XRD detector in accordance with various examples of the present disclosure.

FIG. 4B is a graph of XRD intensity over various fractional rotations in accordance with the first XRD setup of FIG. 4A.

FIG. 4C illustrates a schematic showing derivation of slope direction and intensity in accordance with the first XRD setup of FIG. 4A.

FIG. 4D is a schematic illustrating a derivation of miscut angle and slope direction in accordance with the first XRD setup of FIG. 4A.

FIG. 5A is a perspective view of a second XRD setup having a multiple XRD sources and one or more XRD detectors in accordance with various examples of the present disclosure.

FIG. 5B is a graph of XRD intensity over various angles on a workpiece in accordance with the second XRD setup of FIG. 5A.

FIG. 5C illustrates a graph showing derivation of slope direction and intensity in accordance with the second XRD setup of FIG. 5A.

FIG. 5D is a schematic illustrating a derivation of azimuthal angle and slope direction in accordance with the second XRD setup of FIG. 5A.

FIG. 6 is a top elevation view of another example of an ion implantation system in accordance with various examples of the present disclosure.

FIGS. 7A-7B are top elevation views of an example of a workpiece twist angle orientation in accordance with various examples of the present disclosure.

FIG. 8A-8B illustrate a workpiece tilt angle orientation in accordance with various examples of the present disclosure.

FIG. 9 is a flow diagram of a methodology for characterizing a workpiece positioning using XRD measurements in accordance with various examples of the present disclosure.

### DESCRIPTION OF THE INVENTION

The present disclosure provides a semiconductor processing system and method for increasing an efficiency of a channeled ion implantation. Accordingly, the present invention is described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment and may also or alternatively be fully or partially implemented in a common feature or circuit in another embodiment. For example, several functional blocks may be implemented as software running on a common processor, such as a signal processor. It is further to be understood that any connection which may be described as being wire-based in the following specification may also be implemented as a wireless communication, unless noted to the contrary.

In the manufacture of semiconductor devices, ion implantation is used to dope semiconductors with impurities or dopants. Ion beam implanters are used to treat silicon wafers with an ion beam, in order to produce n- or p-type extrinsic material doping or to form passivation layers during fabrication of an integrated circuit. When used for doping semiconductors, the ion beam implanter injects a selected extrinsic species to produce the desired semiconducting material. Implanting ions generated from source materials such as antimony, arsenic or phosphorus results in “n-type” extrinsic material wafers, whereas if “p-type” extrinsic material wafers are desired, ions generated with source materials such as boron, or indium may be implanted.

Typical ion beam implanters include an ion source for generating positively charged ions from ionizable source materials. The generated ions are formed into a beam and directed along a predetermined beam path to an implantation station. The ion beam implanter may include beam forming and shaping structures extending between the ion source and the implantation station. The beam forming and shaping structures maintain the ion beam and bound an elongated interior cavity or passageway through which the beam passes en route to the implantation station. When operating an implanter, this passageway can be evacuated to reduce the probability of ions being deflected from the predetermined beam path as a result of collisions with gas molecules.

Trajectories of charged particles of given kinetic energy in a magnetic field will differ for different masses (or charge-to-mass ratios) of these particles. Therefore, the part of an extracted ion beam which reaches a desired area of a semiconductor wafer or other target after passing through a constant magnetic field can be made pure since ions of undesirable molecular weight will be deflected to positions away from the beam and implantation of other than desired materials can be avoided. The process of selectively separating ions of desired and undesired charge-to-mass ratios is known as mass analysis. Mass analyzers typically employ a mass analysis magnet creating a dipole magnetic field to deflect various ions in an ion beam via magnetic deflection in an arcuate passageway which will effectively separate ions of different charge-to-mass ratios.

For some ion implantation systems, the physical size of the beam is smaller than a target workpiece, so the beam is scanned in one or more directions in order to adequately cover a surface of the target workpiece. Generally, an electrostatic or magnetic based scanner scans the ion beam in a fast direction and a mechanical device moves the target workpiece in a slow scan direction in order to provide sufficient cover.

Thereafter the ion beam is directed toward a target end station, which holds a target workpiece. Ions within the ion beam implant into the target workpiece, which is ion implantation. One important characteristic of ion implantation is that there exists a uniform angular distribution of ion flux across the surface of the target workpiece, such as a semiconductor wafer. The angular content of the ion beam defines implant properties through crystal channeling effects or shadowing effects under vertical structures, such as photoresist masks or CMOS transistor gates. A non-uniform angular distribution or angular content of the ion beam can lead to uncontrolled and/or undesired implant properties.

In order to achieve high degrees of channeling through a crystal lattice structure, especially at high energies, the ion beam should be angularly aligned with a crystal channel of the crystal lattice structure. Various examples of channeling concepts and ion implantation systems are provided in co-owned U.S. patent No. 9,711,328 to Satoh, the entirety of which is hereby incorporated herein by reference.

Along the direction of the crystal channel, the ion beam can penetrate several times deeper (e.g., 3-5 times deeper) in a so-called channel implant as compared to a non-channel implant having associated with the ion beam not being aligned with the crystal channel at an off-angle. Channel implants are highly desirable for silicon carbide (SiC) wafer processing, since the dopant reaches a desired depth with minimal energy, and a final dopant distribution profile can be obtained as a desirable box-type profile by a single implantation process. Conventionally, a non-channel implant in a wafer can undergo multiple processing with ion beams of varying energy to attain a similar box-type dopant distribution profile.

As such, a channel implant can have various advantages over a non-channel implant, such as enabling lower energy ion implantation for deep and flat profiles, thus allowing for lower energy (e.g., so-called medium current) implantation systems. A channel implant can enable reduced thicknesses of photoresists formed on the wafer, and can reduce a total number of implants required in an implant chain. A process flow associated with channel implants can result in fewer implanters being needed for a given process, thus decreasing tool costs.

However, channel implants have more demanding requirements than non-channel implants, such as a tighter control of an incident beam angle to the wafer, whereby the control should be better than 0.05°, and an overall incident beam angle accuracy should be better than 0.1° with respect to the channel direction. Further, a local miscut angle variation across the wafer typically needs to be kept within 0.05°.

X-ray diffraction (XRD) is a known technique for attaining crystallographic measurements on a wafer for channeling implants, and is typically capable of measuring the miscut angle with 0.01° accuracy for masked, unmasked, patterned, or bare SiC wafers. Conventional XRD can measure a wide range of samples of different thicknesses, and can include varying source and detection angles (called a rocking curve), and a rotation of the wafer can be attained using the appropriate Bragg diffraction intensity. XRD measurement data associated with XRD wafer cut angles provides an azimuthal angle (tilt in degrees) and a polar angle (twist in degrees). As such, for SiC, XRD can provide accurate information related to an off-axis cut angle (e.g., the azimuthal wafer cut angle, or the tilt error with respect to the ideal off-axis cut angle), as well as a crystal cut direction (e.g., the polar angle, or the twist error with respect to an ideal related to a flat or notch position).

For a 4H SiC <0001> wafer, the most common wafer cut angle is ideally 4°. However, an actual miscut angle can deviate significantly (e.g., 4.0°±0.5°), while a 0.01-0.05° angular accuracy with respect to the channel direction is desired. Conventionally, throughput is limited by factors including monitoring and adjusting working distances, such as setting an XRD source and XRD detector at a desired diffraction angle, and rotating the wafer on a goniometer several times in order to adequately attain the measurements. As such, approximately 60 to 180 seconds per wafer are typically required to achieve acceptable data for angular accuracy using traditional XRD techniques. Therefore, throughput of an ion implanter is typically limited by the time taken for the XRD measurement, as the channel implant itself can be typically performed in several seconds.

Various systems and methods have been proposed to integrate conventional XRD measurement in an ion implantation system, but have been met with various limitations. For example, an in-situ XRD measurement process has been described that is performed within an implantation chamber on a wafer positioned on a process chuck, just prior to an implantation of ions from an ion beam onto the wafer. As such, each wafer must follow a predetermined sequence, whereby the wafer is loaded onto the process chuck, and an XRD measurement is performed within the implantation chamber, whereby a process recipe is calculated to determine a twist and tilt position of the process chuck (and thus, the workpiece). A position of the process chuck is then adjusted to control the twist and tilt position with respect to the ion beam that is suitable of the implantation, and only then is the wafer implanted by the ion beam and subsequently removed or unloaded from the process chuck and implantation chamber. In such an XRD measurement process, the wafer remains on the process chuck during the entire sequence, thus leading to an extensive processing time for the wafer and limiting a productivity of the implantation process.

As opposed to the XRD measurement being performed in the implantation chamber, Japanese Patent JP711637B2 to Nissin teaches another XRD measurement process, whereby an XRD measurement is performed in a wafer transferring system. The present disclosure appreciates that if the XRD measurement is performed in the wafer transferring system, the wafer may suffer from robot positioning error, particularly errors in the twist direction. Further, utilization of different chucks may lead to variations in wafer bow seen on the wafer, whereby the ion beam can present various wafers at different incident angles, leading to non-uniformities in channeling.

The present disclosure appreciates that for both conventional XRD measurement processes, the time taken for the XRD measurement is typically longer than implantation process, and as such, can deleteriously impact productivity of the implantation system, even if parallelized with ion implantation. Various limitations are presented in the prior art, such as error or drift associated with scanning the ion beam over the entire wafer. Further, a silicon carbide (SiC) wafer can be prone to deformation associated with various processes performed on the wafer, and a deformation such as a bow may not be corrected by the chuck clamping the wafer to the surface of the chuck. Further, the ion implantation process or the temperature of the processing may lead to stresses in wafer, thus further inducing an unexpected bow in the wafer. All of these phenomena may impact the incident angle of the ion beam across the wafer, and can induce substantial non-uniformities in the ion implantation across the wafer.

The present disclosure appreciates that conventional systems and methods for performing XRD measurements on a workpiece can have substantial limitations and can negatively affect a throughput of workpieces processed through an ion implantation system. Accordingly, an ion implantation system and method are provided herein, whereby an ion implantation process and an XRD measurement can be performed accurately and in parallel, while minimizing a total sequence time of the ion implantation and XRD measurement process.

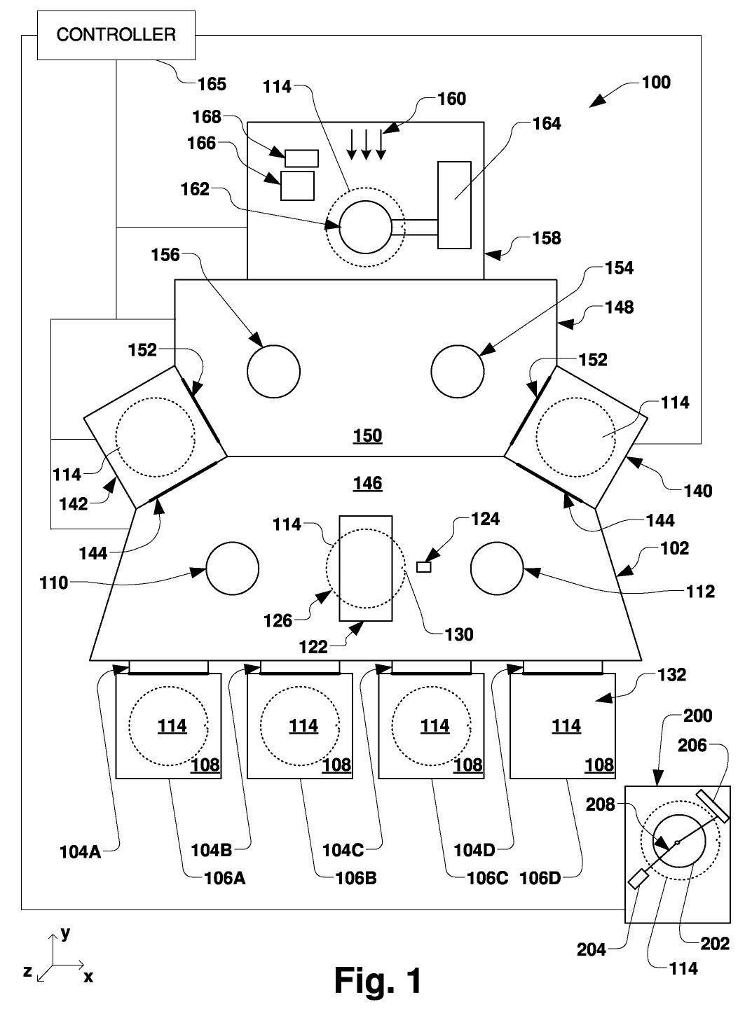

Referring now to the figures, FIG. 1 illustrates an ion implantation system 100 in accordance with one exemplary aspect of the present invention. The ion implantation system 100 of FIG. 1, for example, can comprise one or more features described in co-owned US Patent No. 10,832,926 to Joseph Ferrara, et al., the contents of which are incorporated by reference herein, in their entirety. The ion implantation system 100 illustrated in FIG. 1 of the present disclosure, for example, comprises a front end module 102, wherein the front end module comprises one or more load ports 104A-104D operable to receive one or more workpiece transport containers 106A-106D. Each of the load ports 104A-104D, for example, is configured to provide selective communication between the respective workpiece transport containers 106A-106D and the front end module 102. The workpiece transport containers 106A-106D, for example, comprise Front Opening Unified Pods (FOUPs) 108, wherein each FOUP is operable to interface with the front end module 102.

The front end module 102 of the present example comprises a first robot 110 and a second robot 112. The first robot 110, for example, is configured to load and unload a workpiece 114 (e.g., a silicon carbide (SiC) wafer) from each of the respective workpiece transport containers 106A and 106B, and the second robot 112 is configured to load and unload respective workpieces from the workpiece transport containers 106C and 106D. Each of the first robot 110 and second robot 112, for example, are capable of multiple degrees of freedom including vertical, radial and azimuthal movements.

In one example, the front end module 102 further comprises an alignment apparatus 122 disposed generally between the first robot 110 and the second robot 112, wherein the alignment apparatus is configured to determine an alignment of the workpiece 114. The alignment apparatus 122, for example, comprises one or more characterization devices 124 configured to detect one or more characteristics associated with the workpiece 114 when the workpiece at a characterization position 126.

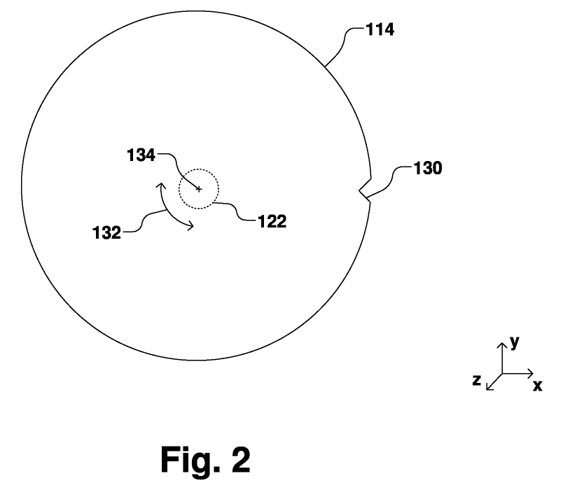

In one example, the one or more characterization devices 124 may include an optical sensor such as a camera, or other detection device, that is configured to detect a position indicia 130 (e.g., a notch, flat, or other physical characteristic) associated with the workpiece 114. As illustrated in FIG. 2, the alignment apparatus 122, for example, can be configured to selectively rotate (illustrated as arcuate arrow 132) the workpiece 114 about an axis 134. Accordingly, the alignment apparatus 122 can be configured to further determine a position of the position indicia 130 via the rotation of the workpiece 114 with respect to the optical sensor 128. The position of the position indicia 130 determined by the alignment apparatus 122, for example, may be utilized to further selectively orient or identify a position of the workpiece 114 for subsequent processing.

In accordance with another aspect of the invention, the ion implantation system 100 of FIG. 1 further comprises a first load lock module 140 and a second load lock module 142 operably coupled to the front end module 102, wherein the workpiece 114 may be transferred between the front end module and the first or second load lock modules. Each of the first load lock module 140 and the second load lock module 142 comprise respective first isolation doors 144 associated with the front end module 102, wherein the respective first isolation doors selectively fluidly couples an internal volume the respective first and second load lock module to an internal environment 146 of the front end module.

The ion implantation system 100, for example, further comprises a vacuum module 148 operably coupled to the first load lock module 140 and the second load lock module 142, wherein the vacuum module comprises a generally evacuated internal environment 150. Each of the first load lock module 140 and the second load lock module 142 further comprise respective second isolation doors 152, wherein the respective second isolation doors selectively fluidly couples the first load lock module and the second load lock module to the evacuated internal environment 150 of the vacuum module 148. One or more high vacuum pumps (not shown) may be operably coupled to the vacuum module 148, therein generally evacuating the vacuum module. The vacuum module 148, for example, comprises a third robot 154 and a fourth robot 156 disposed therein, wherein each of the third and fourth robots, for example, are capable of multiple degrees of freedom including vertical, radial and azimuthal movements.

The vacuum module 148, for example, is further operably coupled to a process chamber 158 configured to receive an ion beam 160. The process chamber 158, for example, may comprise an electrostatic chuck 162 disposed therein, wherein the electrostatic chuck is configured to individually selectively support the workpiece 114. The process chamber 158 may further comprise a processing robot 164 configured to translate the electrostatic chuck 162 through the ion beam 160 for implanting ions into the workpiece 114. The third robot 154 and the fourth robot 156, for example, are configured to selectively transport the workpiece between the electrostatic chuck 162 and the first load lock module 140 and the second load lock module 142.

The present disclosure appreciates that, in order to achieve high degrees of channeling through a crystal lattice structure of the workpiece 114, such that of a silicon carbide wafer, the ion beam 160 should be angularly aligned with the crystal lattice structure of the workpiece. The present disclosure contemplates x-ray diffraction (XRD) as being a useful technique for determining the crystal lattice structure of the workpiece 114. Conventionally, XRD techniques have been performed within ion implantation systems, whereby a position of the workpiece is rotated several full 360° rotations, while an XRD source and XRD detector are translated or otherwise manipulated in order to adjust for each measurement taken. Further, a chuck or stage on which the workpiece is held must be adjusted based on goniometer measurements, and a tilt of the stage must be adjusted, as well as a distance at which the measurements are taken for each workpiece measurement. The conventional XRD techniques can lead to significant throughput limitations, as an XRD measurement can take significantly longer (e.g., between 60-180 seconds) and be longer than the ion implantation itself.

The present disclosure contemplates various XRD techniques for characterizing the crystalline structure of the workpiece 114, while not substantially affecting throughput of the ion implantation system 100. Accordingly, the present disclosure contemplates the ion implantation system 100 of FIG. 1 comprising an XRD module 200 that can be substantially disconnected or otherwise isolated from or external to the process chamber 158, the vacuum module 148, and/or the front end module 102, thereof. As such, XRD measurements can be performed separately from the movement of the workpiece 114 between the process chamber 158, the vacuum module 148, and/or the front end module 102. The XRD module 200, for example, comprises an XRD chuck 202 (e.g., a vacuum chuck configured for 150mm and/or 200mm SiC wafers), whereby an even gripping force can be exerted across the workpiece 114 to minimize the wafer bow. The XRD module 200, for example, further comprises an XRD source 204 (e.g., an x-ray source), and an XRD detector 206, whereby the XRD detector is configured to detect diffracted x-rays 208 emitted from the XRD source.

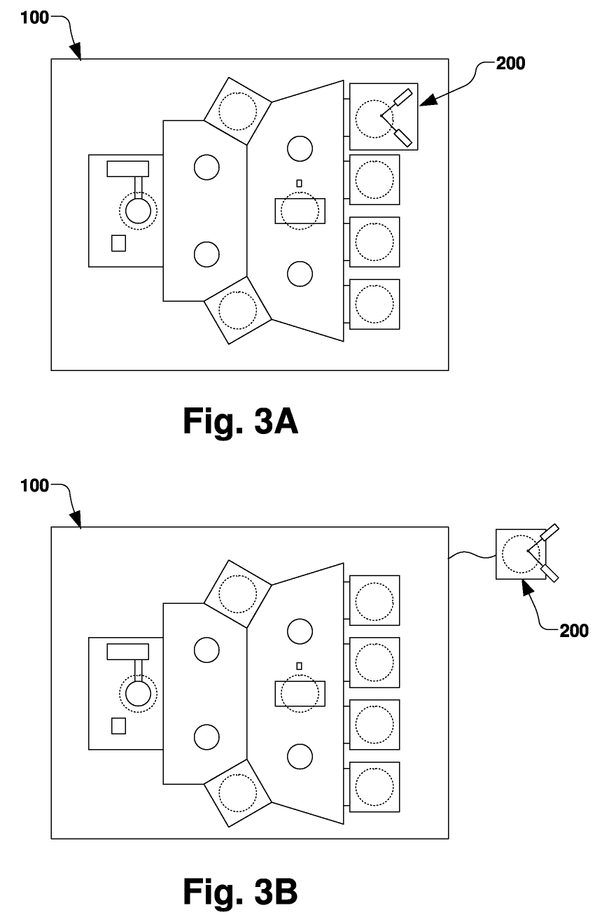

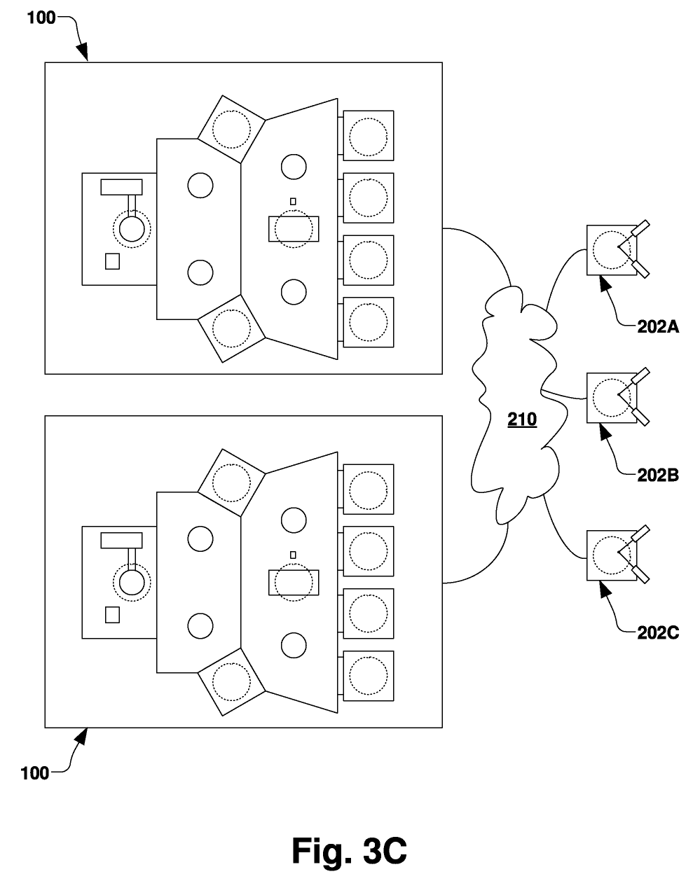

In accordance with one example, one of the load ports 104A-104D may be operably coupled to the XRD module 200. For example, the workpiece transport container 106D may be replaced with the XRD module 200, such that the load port 104D can be configured to provide selective communication between the XRD module and the front end module 102, as illustrated in FIG. 3A. In another example, the XRD module 200 can be physically isolated from the ion implantation system 100, as illustrated in FIG. 3B, whereby the characterization of the workpiece 114 can be performed remotely and logically coupled to the workpiece, such that data associated with the characterization of the workpiece is attached virtually ( e.g., via computer) to the workpiece. Accordingly, XRD measurements and ion implantation can be performed in parallel, thus optimizing throughput of workpieces through the ion implantation system. According to another example, as illustrated in FIG. 3C, a plurality of XRD modules 200A-200C may be provided and be physically isolated from one or more ion implantation systems 100, whereby each workpiece can be characterized and measurement data associated with each workpiece can be stored in a storage medium 210.

Accordingly, the present disclosure contemplates the XRD module 200 operating independently from the implantation of ions into the workpiece 114 in the process chamber 158, thus maximizing productivity of both XRD measurements and ion implantation. As such, each of the XRD module 200 and the implantation on ions in the process chamber 158 may be operated independently, such that a malfunction or maintenance in one system or module does not affect the other system or module. Further, the present disclosure contemplates a network of XRD systems or XRD modules and implantation systems, whereby any number of systems can be activated as backup systems, thus providing alternate process pathways in the event of breakdown.

The present disclosure contemplates any of the XRD modules 200 of FIGS. 3A-3C being configured to further define fingerprint data associated with each workpiece, whereby the XRD measurements for each workpiece can be uniquely identified. As such, accurate positioning of the workpiece with respect to the ion beam may be attained based on a unique identifier for each workpiece and the XRD measurements associated therewith. For example, the XRD module 200 can be configured to determine and match a relative position between each workpiece 114 on the chuck 162 in the process chamber 158 and XRD chuck. This ensures similar performance of in situ approach but with the possibility to parallelize the sequence.

For example, the present disclosure contemplates that when the workpiece is properly clamped on an ideal chuck, a flatness or topography of the workpiece can be considered unique. For example, the topography of the workpiece 114 can be obtained by a confocal displacement sensor-optics technique, whereby the physical surface (e.g., bow, warp, and tilt) can be mapped with high accuracy. Such optics are integrated and can acquire or otherwise determine parameters associated with flatness of the workpiece during the XRD measurement. The acquired parameters, for example, can thus be tagged or otherwise associated with the workpiece as a “fingerprint,” whereby the fingerprint follows the workpiece throughout its processing. As such, the flatness parameters can be communicated either directly to the ion implanter, or indirectly via a central or a controller 165 in the processing network.

A processing chamber identification system 166 of FIG. 1, for example, can be further implemented within the process chamber 158, whereby a first fingerprint is taken by the XRD module 200, and a second fingerprint of the workpiece 114 is again acquired when the workpiece is positioned on the chuck 162 just prior to the implantation. A comparison between the first and second fingerprints, for example, can allow for a determination as to whether any errors have been induced during transferring the workpiece throughout the ion implantation system 100, such as a determination of a twist of the workpiece relative to the ion beam 160. The present disclosure contemplates various other methods for determining the fingerprint, such as mapping of various position(s) of alignment marks, workpiece ID, or other indicia or patterns (e.g., a difference of an acquired pattern image from a predetermined reference pattern image) associated with the workpiece 114. Such a fingerprint can be attained before processing, thereby allowing for a correction of errors that may occur during transfer of the workpiece 114 from the XRD module 200 to the chuck 162. The fingerprint, for example, may be utilized to associate a direction of channeling in the workpiece 114 with respect to a position of the workpiece during the XRD measurement, whereby the position may be reproduced in the process chamber 158 prior to the implantation of ions into the workpiece. Further, the fingerprint may be utilized for various other process monitoring procedures, whereby the processing of workpieces may be halted when errors are unexpected or exceed predetermined limits or thresholds.

Further, the present disclosure contemplates each workpiece 114 being uniquely identified to include, for example, a topography mapping of each workpiece, whereby the XRD module 200 is configured to detecting a bow or variation of the incident angle received by the XRD detector 206. Key performance indicators (KPI) may be further applied to monitor each workpiece 114, whereby processing of workpieces may be halted if a variability in KPI exceeds a predetermined threshold.

The present disclosure further contemplates a configuration of the XRD module 200 to detect incident angle during processing of workpieces for verification that incident angles do not vary during processing, such as by robot movement, stress induced by the ion beam, etc.

The present disclosure thus overcomes throughput limiting factors conventionally seen by providing the XRD module 200 such that XRD measurements can be performed without affecting throughput of workpieces in the ion implantation process. In particular, the present disclosure improves throughput by determining a so-called miscut angle associated with the crystalline structure of the workpiece 114. The so-called cut angle has a margin of error that must be kept within narrow angular band (e.g., within ±0.5°), where the Bragg intensity has a peak and varies for small incident angle changes (e.g., changes of 0.01° or smaller), but are still detectable.

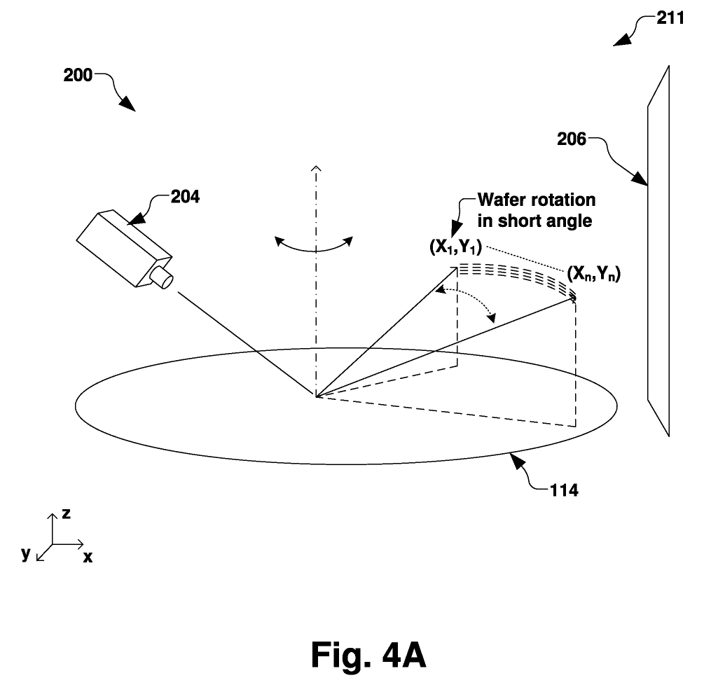

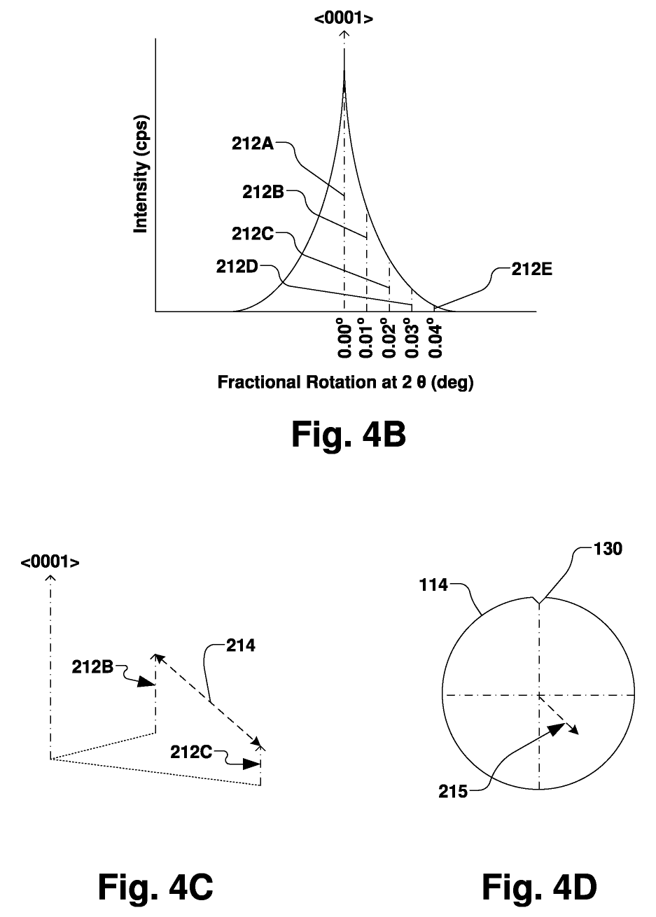

In order to detect the miscut angle, the present disclosure contemplates various configurations of the XRD module 200. For example, as illustrated in a first setup 211 in FIG. 4A, the XRD source 204 (e.g., X-ray optics configured as a single-focus source) and the XRD detector 206 (e.g., a fixed detector array) are provided in fixed positions with respect to the workpiece 114, whereby the workpiece is fixed in the x-y plane and permitted to fractionally rotate (e.g., twist) about the z-axis. FIGS. 4B-4D, for example, illustrate how an azimuthal angle and a polar angle can be derived from the fractional twist of the workpiece 114 of FIG. 4A, whereby multiple measurements of XRD intensities 212 can be taken at n points ranging from (X₁, Y₁) to (Xₙ,Yₙ) via the XRD module 200 concurrent with the fractional rotation of the workpiece. For example, an azimuthal slope (also called tilt) and slope direction (also called twist or polar twist angle) can be derived from a variation in any number of XRD intensities 212 measured from points (X₁, Y₁) to (Xₙ,Yₙ) by the XRD detector 206 as the workpiece 114 is fractionally rotated.

In the example of FIG. 4B, five XRD intensities 212A-212E are illustrated for simplicity at various fractional rotations, whereby XRD intensity 212A is illustrated as being along the crystal plane (e.g., <0001>) and XRD intensities 212B-212E are off-axis to the crystal plane in a narrow angular band of channel sensitivity. FIG. 4C illustrates an example showing how XRD intensity 212B at (X₁, Y₁) and XRD intensity 212C at (X₂,Y₂) can be utilized to derive the slope direction and intensity 214 from the fractional rotation, while FIG. 4D schematically illustrates the derivation 215 of miscut angle (e.g., azimuthal tilt angle) and slope direction (e.g., polar twist angle) with respect to the position indicia 130 of the workpiece 114 from the variation in XRD intensities 212 described above.

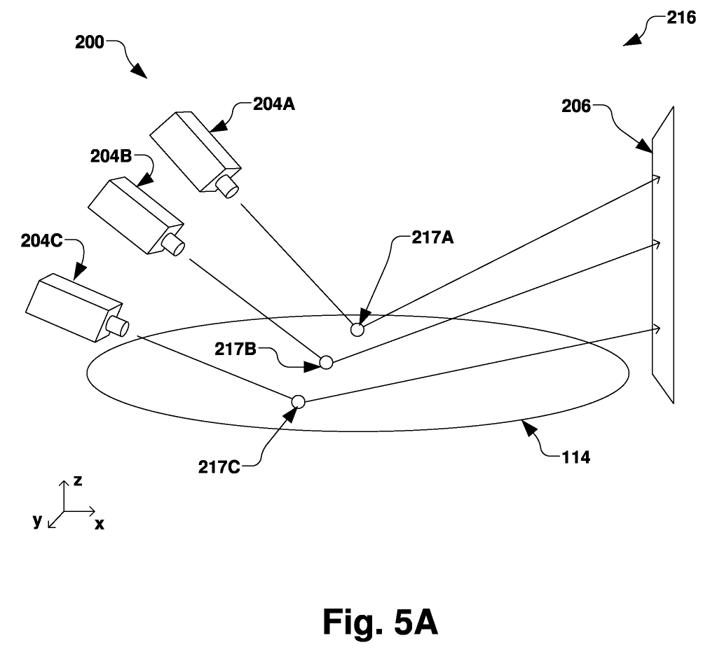

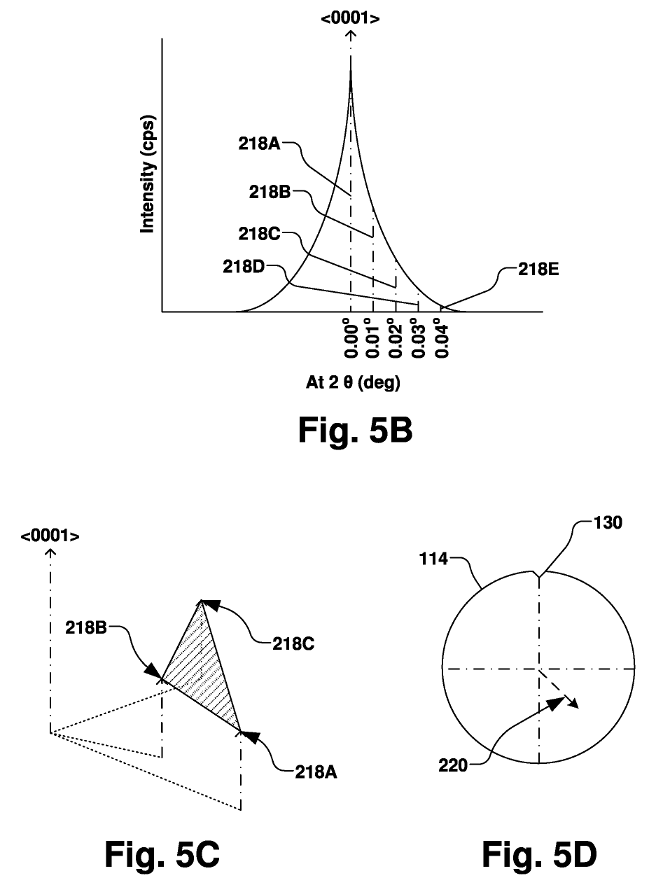

In another example illustrated in FIG. 5A, a second setup 216 is illustrated having a plurality of XRD sources 204A, 204B, 204C (e.g., three X-ray optic sources are illustrated, while any number m of X-ray sources are contemplated) and one or more XRD detectors 206 (e.g., one or more fixed detector arrays) are provided with respect to the workpiece 114, whereby the workpiece is fixed in the x-y plane as well as being rotationally fixed about the z-axis. The plurality of XRD sources 204A, 204B, 204C, for example, are respectively fixedly directed toward a plurality of focus points 217A, 217B, 217C along the workpiece 114 (e.g., along the x-y plane). Similar to FIG. 4B, the example illustrated in FIG. 5B shows five XRD intensities 218A-218E that are illustrated for simplicity, whereby XRD intensity 218A is illustrated as being along the crystal plane (e.g., <0001>) and XRD intensities 218B-218E are off-axis to the crystal plane in a narrow angular band of channel sensitivity.

In the present whereby measurements of XRD intensities 218 can be taken at the plurality of focus points 217A, 217B, 217C, whereby as illustrated in FIG. 5C, an azimuthal slope can be derived from the XRD intensities 218A-218C measured from focus point 217A at (X ₁, Y₁), focus point 217B at (X₂,Y₂), and focus point 217C at (X₃,Y₃), by the XRD detector 206. FIG. 5C, for example, illustrates an example showing how XRD intensity 218B at (X₁, Y₁), XRD intensity 218C at (X₂, Y₂), and XRD intensity 218D at (X₃,Y₃) can be utilized to triangulate and derive the tilt and slope based on the XRD intensities measured by the XRD detector 206. FIG. 5D schematically illustrates the derivation 220 of miscut angle (e.g., azimuthal tilt angle) and slope direction (e.g., polar twist angle) with respect to the position indicia 130 of the workpiece 114 from the variation in XRD intensities 218 described above.

For both the first setup 211 and the second setup 216 of FIGS. 4A and 5A, a “narrow band XRD intensities at channel direction” is predetermined, and respective angles of the respective XRD source 204 and the XRD detector 206 are set to predetermined values to attain Bragg diffraction peak intensities at the channel direction. For the first setup 211 of FIG. 4A, for example, XRD intensities are measured along the circle fraction path (e.g., 1/6th – 1/10th of 360°) by a fractional rotation of the workpiece 114 about the z-axis. In the second setup 216 of FIG. 5A, for example, multiple focus points 217 are provided with no rotation of the workpiece 114 about the z-axis to derive azimuthal (e.g., the tilt portion of the wafer cut angle) and polar angle (e.g., the twist portion of wafer cut angle) parameters.

Unlike traditional XRD measurement systems, both the first setup 211 and the second setup 216 of respective FIGS. 4A and 5A do not require continuous movement of the XRD source or XRD detector, nor do they require a goniometer for holding the workpiece 114. Further, conventional XRD measurement systems typically require several rotations of workpieces during measurement (e.g., taking approximately 60-180 seconds) in order to generate the wafer cut angle data. The XRD wafer cut angle data derived by the XRD module 200 of the present disclosure is achieved from multi point XRD intensities, either by a fractional rotation of the workpiece 114 in the first setup 211 of FIG. 4A, or from multi-X-ray focus points in the second setup 216 of FIG. 5A, having a fixed position of the XRD source 204, the XRD detector 206, and the workpiece 114 (except for a fractional wafer rotation on Z-axis).

The wafer cut angle data is represented as azimuthal (e.g., the so-called tilt portion of the wafer cut angle) and as a polar angle (e.g., the so-called twist portion of wafer cut angle) parameters, as indicated in FIGS. 4B-4D and FIGS. 5B-5D. The tilt and twist of the wafer cut angle with respect to the position indicia 130 of FIG. 1 (e.g., the notch or flat discussed above) is measured at atmospheric conditions at the load port 104A-104D, at the alignment apparatus 122, or at the load lock modules 140, 142. For example, the XRD measurement techniques and application twist portion of the wafer cut angle of the present disclosure is already set with respect to notch or flat position predetermined at the load port 104A-104D or at a pre-alignment prior to the XRD measurement, and can be considered as feed-forward information.

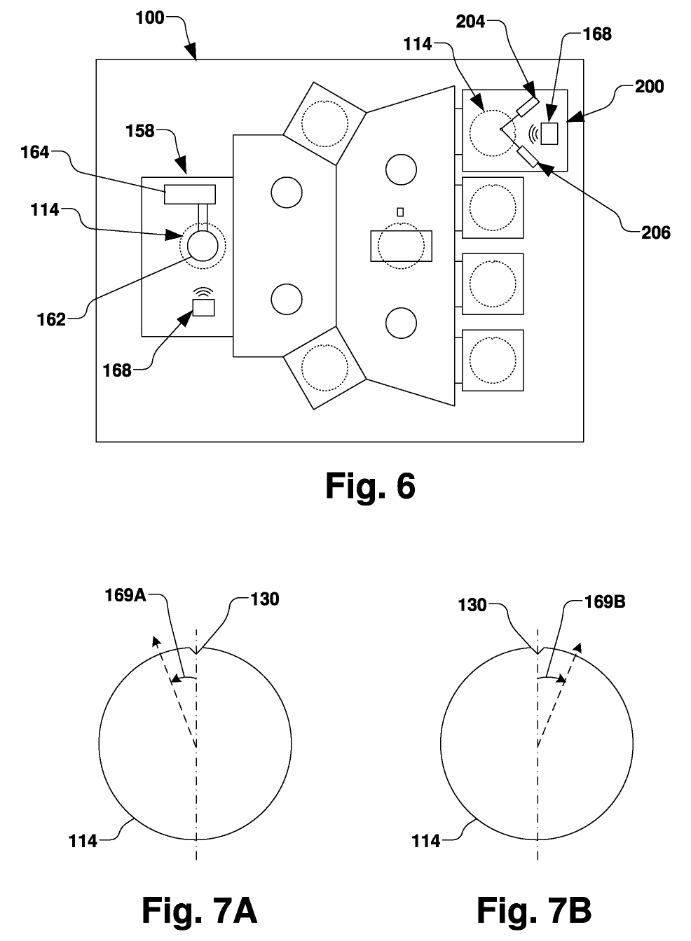

In one example, a confocal displacement sensor-optics apparatus 168 can be provided in the process chamber 158, as well as in the XRD module 200, as illustrated in FIG. 6, in order to confirm and/or correct the final the wafer twist and tilt on the electrostatic chuck 162 within the process chamber. Based on the XRD measurements, the tilt portion of the wafer cut angle, for example, can be corrected in the process chamber 158 on the electrostatic chuck 162 by the processing robot 164 of FIG. 1 as a feed forward information. For example, the workpiece 114 may be aligned at 0° incident to the channel direction by tilting the chuck in one direction and/or changing the horizontal and/ or vertical beam angle as necessary.

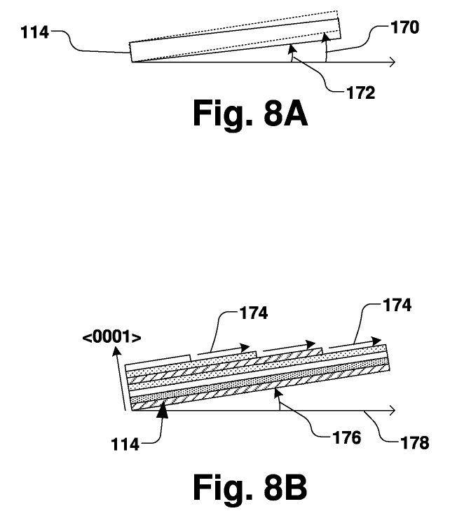

The present disclosure further contemplates an angle measurement system for detecting incident angle of the ion beam 160 during processing of the workpiece 114. FIG. 7A, for example, illustrates a measured twist orientation 169A of the workpiece 114, and FIG. 7B illustrates a twist correction 169B applied to the workpiece 114 in accordance with the present disclosure, whereby the workpiece can be aligned with the ion beam discussed above. FIG. 8A, for example, illustrates measured tilt orientation 170 (e.g., the so-called cut off angle) of the workpiece 114, whereby a tilt correction 172 can be applied to the workpiece 114. Accordingly, by applying the tilt correction 172 of FIG. 8A, a layer growth direction 174 relative to a trench direction 178 shown in FIG. 8B can be properly aligned with an off-axis cut angle 176.

For example, a tilt angle and a twist angle of the workpiece 114 with respect to the ion beam 160 of FIG. 1 can be indirectly controlled by a motor encoder via the controller 165. Furthermore, assuming the workpiece 114 is initially accurately positioned on the electrostatic chuck 162 in the process chamber 158, the present disclosure contemplates the workpiece moving during processing through the ion beam 160 in order to allow the scan of the ion beam across the entire workpiece. Further, the ion implantation may induce stresses on the workpiece 114, thereby inducing an additional bow or warp that may not be fully compensated for by the clamping force exerted by the electrostatic chuck 162.

Accordingly, the angle measurement system can comprise a laser measuring apparatus associated with the process chamber, whereby the angle measurement system is configured to independently determine a tilt measurement prior to processing of the workpiece through the ion beam 160. For example, such a tile measurement can serve as a consistency check between the chuck 162 (e.g., an encoder associated with the chuck) and the laser-based angle measurement, whereby the tilt can be corrected, if necessary. Further, variations in tilt during the ion implantation process can be determined by the angle measurement system.

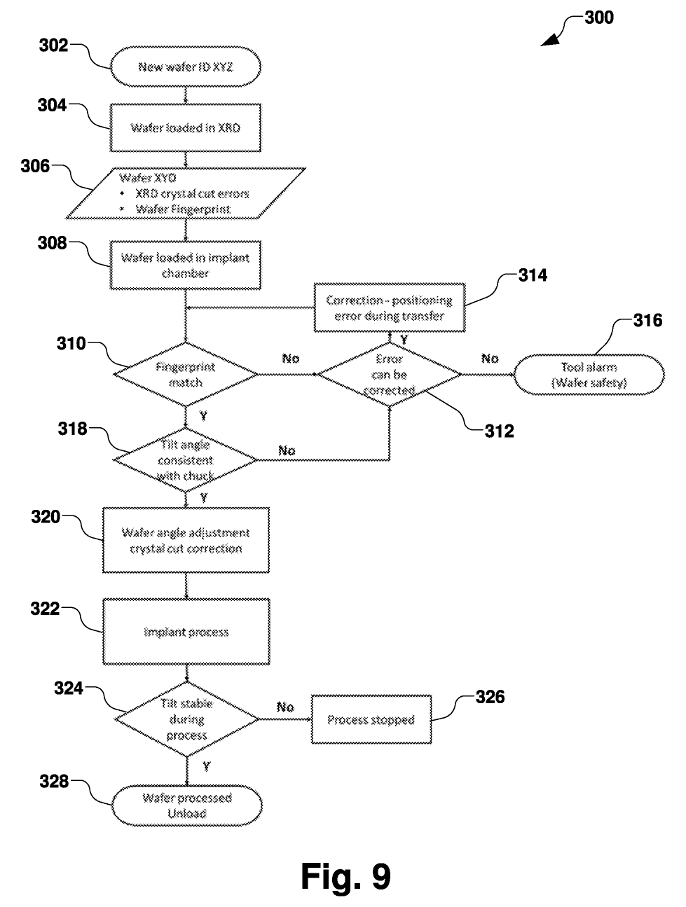

In accordance with various aspects of the present disclosure, FIG. 9 further illustrates a method 300 for characterizing a workpiece undergoing ion implantation. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 begins at act 302, whereby a wafer or workpiece is identified (e.g., ID XYZ). In act 304, the wafer is loaded into the XRD module 200 of FIG. 1, whereby XRD measurements are acquired in act 306 of FIG. 9. In act 308, the wafer is loaded into the process chamber 158 of FIG. 1, and a fingerprint match is determined in act 310 of FIG. 9. If the fingerprint of the wafer is not matched in act 310, a determination is made in act 312 as to whether such an error can be corrected. If the fingerprint match error can be corrected, an appropriate correction of positioning error is performed in act 314, and the fingerprint match is again determined in act 310. If the fingerprint match error cannot be corrected, an alarm or other appropriate action is performed in act 316, whereby the wafer is determined to not be in compliance (e.g., subsequent processing of the wafer is halted).

If the fingerprint of the wafer is matched in act 310, a determination is made in act 318 as to whether the tilt angle is consistent with the angle of the chuck holding the wafer. If the tilt angle is not consistent with the angle of the chuck holding the wafer by the determination in act 318, the determination is again made in act 312 as to whether the error can be corrected. If the tilt angle is consistent with the angle of the chuck holding the wafer by the determination in act 318, any appropriate wafer angle adjustment is performed in act 320 to provide the appropriate desired crystal cut correction. Accordingly, the ion implantation is performed on the wafer in act 322, whereby a determination is made in act 324 as to whether the tilt is stable concurrent with the ion implantation process. If the tilt is not stable concurrent with the ion implantation process, the ion implantation process is halted in act 326. If the tilt is determined to be stable concurrent with the ion implantation process in act 324, the implantation process is completed, and the wafer is further processed and unloaded from the system in act 328.

Although the invention has been illustrated and described with respect to one or more implementations, it will be understood that alterations and/or modifications may be made to the illustrated examples without departing from the spirit and scope of the appended claims. In particular regard to the various functions performed by the above described components or structures (blocks, units, engines, assemblies, devices, circuits, systems, etc.), the terms (including any reference to a "means") used to describe such components are intended to correspond, unless otherwise indicated, to any component or structure which performs the specified function of the described component ( e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms "including", "includes", "having", "has", "with", or variants thereof are used in either the detailed description and the claims, such terms are intended to be inclusive in a manner similar to the term "comprising".

What is claimed is:

1. A method for implanting ions into a crystalline lattice of a workpiece, the method comprising:
positioning the workpiece on a first workpiece support, wherein the workpiece comprises an alignment feature;
detecting a first position of the workpiece with respect to the first workpiece support;
directing one or more emission x-rays from one or more x-ray sources toward the workpiece when the workpiece is positioned on the first workpiece support, wherein the one or more emission x-rays are diffracted from the workpiece to define one or more diffraction x-rays, respectively;
detecting the one or more diffraction x-rays;
determining one or more angles associated with the crystalline lattice of the workpiece based on the one or more diffraction x-rays and the first position of the alignment feature of workpiece with respect to the one or more x-ray sources, thereby defining a workpiece profile with respect to the alignment feature of the workpiece;
transferring the workpiece to second workpiece support;
detecting a second position of the workpiece with respect to the second workpiece support;
controlling a position of the second workpiece support with respect an ion beam based on the workpiece profile and the second position of the alignment feature of the workpiece; and
implanting ions from the ion beam into the workpiece.

2. The method of claim 1, wherein detecting the first position of the workpiece with respect to the first workpiece support comprises detecting a position indicia defined on the workpiece.

3. The method of claim 2, wherein detecting the position indicia is performed in an atmospheric environment.

4. The method of claim 2, wherein the position indicia comprises one or more of a notch or a flat defined along a periphery of the workpiece.

5. The method of claim 1, wherein the second workpiece support comprises an electrostatic chuck positioned within a process chamber.

6. The method of claim 1, wherein the one or more x-ray sources are fixed in position with respect to the first workpiece support.

7. The method of claim 6, wherein determining the one or more angles associated with the crystalline lattice of the workpiece comprises rotating the workpiece with respect to one or more one or more x-ray sources.

8. The method of claim 6, wherein the one or more x-ray sources comprises a plurality of x-ray sources, and wherein determining the one or more angles associated with the crystalline lattice of the workpiece comprises fixing a rotational position of the workpiece concurrent with detecting the one or more diffraction x-rays.

9. An ion implantation system, comprising:
an ion source configured to form an ion beam;
a beam line assembly configured to direct the ion beam;
a process chamber configured to receive the ion beam;
a process chuck positioned within the process chamber, wherein the process chuck is configured to selectively support a workpiece with respect to the ion beam;
an x-ray diffraction measurement apparatus located external to the process chamber, the x-ray diffraction measurement apparatus comprising:
a measurement station comprising a measurement chuck configured to selectively support the workpiece;
an x-ray source configured to direct one or more emission x-rays toward the workpiece when the workpiece is supported on the measurement chuck, wherein the one or more emission x-rays are diffracted from the workpiece to define one or more diffraction x-rays, respectively; and
an x-ray detector configured to detect the one or more diffraction x-rays; and
a controller configured to control a position of the process chuck based, at least in part, on the one or more diffraction x-rays.

10. The ion implantation system of claim 9, wherein the x-ray diffraction measurement apparatus further comprises a manipulation apparatus operably coupled to the measurement chuck and configured to selectively position the workpiece with respect to the one or more emission x-rays.

11. The ion implantation system of claim 10, wherein the x-ray source is fixed in position with respect to the measurement station.

12. The ion implantation system of claim 11, wherein the manipulation apparatus is configured to selectively rotate the measurement chuck with respect to the x-ray source.

13. The ion implantation system of claim 10, comprising a plurality of x-ray sources configured to direct a respective plurality of x-rays toward the workpiece at a respective plurality of angles with respect to the workpiece, wherein the plurality of x-ray sources are fixed in position with respect to the measurement station.

14. The ion implantation system of claim 9, further comprising a load port associated with a load chamber, wherein the load chamber is external to the process chamber and is operably coupled to the process chamber, and wherein the x-ray diffraction measurement apparatus is associated with the load port.

15. The ion implantation system of claim 9, wherein the x-ray diffraction measurement apparatus is positioned at a remote location.

16. The ion implantation system of claim 9, further comprising a detection apparatus configured to detect one or more features of the workpiece.

17. A method for processing a wafer, the method comprising:
identifying the wafer;
loading the wafer into an XRD module;
acquiring XRD measurements associated with the wafer;
positioning the wafer on a chuck in a process chamber, thereby defining a wafer position;
determining if a fingerprint of the wafer is matched with a predetermined wafer profile based, at least in part, on the XRD measurements and defining a match error if the fingerprint of the wafer is inconsistent with the predetermined wafer profile;
determining if the match error can be corrected by a corrective action;
performing the corrective action If the match error can be corrected;
setting a non-compliant alarm action if the match error cannot be corrected;
determining whether a tilt angle of the wafer is consistent with an angle of the chuck based, at least in part, on the XRD measurements and redefining the match error if the tilt angle of the wafer is inconsistent with the angle of the chuck;
performing a wafer angle adjustment based, at least in part, on the XRD measurements, to provide a desired crystal cut; and
performing an ion implantation on the wafer after the wafer angle adjustment is performed.

18. The method of claim 17, wherein the match error comprises a positioning error associated with the wafer position, and wherein the corrective action comprises a correction to the wafer position.

19. The method of claim 17, further comprising determining whether the tilt angle of the wafer is stable concurrent with the ion implantation being performed on the wafer.

20. The method of claim 19, further comprising halting the ion implantation if the tilt angle is not stable concurrent with the ion implantation.
